(19) United States
(12) Patent Application Publication
(10) Pub. No.: US 2013/0146270 A1
(43) Pub. Date: Jun. 13, 2013

(54) FIXING DEVICE, AND HEAT SINK DEVICE OR SHIELD CASE COMPRISING THE SAME

(71) Applicants: Ping An, Shanghai (CN); Xuefeng Tang, Shanghai (CN); Su Cui, Shanghai (CN)

(72) Inventors: Ping An, Shanghai (CN); Xuefeng Tang, Shanghai (CN); Su Cui, Shanghai (CN)

(73) Assignee: DELTA ELECTRONICS (SHANGHAI) CO., LTD., Shanghai (CN)

(21) Appl. No.: 13/488,606

(22) Filed: Jun. 5, 2012

(30) Foreign Application Priority Data
Dec. 13, 2011 (CN) 201110413312.1

(51) Int. Cl. F28F 7/00; H05K 7/20

(52) U.S. Cl. 165/185; 248/224.8

(57) ABSTRACT

A fixing device, and a heat sink device or a shield case comprising the same. The fixing device is used to connect the heat sink device or the shield case to a circuit board. The circuit board has a via hole which comprises a first size, a second size, and a first height. The fixing device has a connecting member which comprises successively along its extending direction a first boss part, a clamping part, and a second boss part. The first boss part has a first width; the clamping part engages with the via hole, and has a second width and a second height; the second boss part has a third width. The third width is smaller than the second size, the second width equals to the first size, the second height equals to the first height, and the first and third width are larger than the first size.

### CROSS-REFERENCE TO RELATED APPLICATIONS

This non-provisional application claims priority under 35 U.S.C. § 119(a) on Patent Application No(s). 201110413312.1 filed in P.R. China on Dec. 13, 2011, the entire contents of which are hereby incorporated by reference.

### FIELD OF THE INVENTION

The present invention relates to a fixing device, and particularly to a fixing device for a heat sink device or a shield case, as well as a heat sink device and a shield case comprising the fixing device.

### BACKGROUND OF THE INVENTION

A heat sink device or a shield case is a device which is to be inserted into a circuit board and fixed onto the same by soldering, and is widely applied in the power supply, as well as in products relating with network, industrial, and civil apparatuses.

For instance, a power adapter for a notebook computer mainly consists of housing and a heat sink device, as well as various internal electronic components. Reference is made to the structure of a heat sink device in a conventional power adapter for a notebook computer. As shown in FIG. 1, a fixing device 20 is arranged on the heat sink device 10. The fixing device 20 on the heat sink device 10 comprises a base member 21 and a connecting member 22 which is perpendicular to the base member 21. In the base member 21 is provided with a via hole 211. In the heat sink device 10 is provided with a via hole (not shown) corresponding to the via hole 211. A locking member 30 passes through the via hole 211 and 11 for locking the fixing device 20 onto the heat sink device 10. The connecting member 22 comprises a boss 221 and a connecting part 222 which penetrates the via hole in the circuit board, so that the heat sink device 10 is fixed with respect to the circuit board. In such a manner for fixing the heat sink device, the power adapter for a notebook computer imposes a strict requirement on the size, the internal components are closely packed, and there is hardly any spare space. When soldered, the fixing device 20 is prone to buckle. As a result, once the power adapter is assembled, a gap exists between the upper and lower housing, and electrical testing regarding safety regulation and the like fails, which may influence the quality of products. Besides, after the connecting part extends out of the via hole in the circuit board, a soldering is required to fix the fixing device with respect to the circuit board. This may lead to waste of time and human resources due to the complicated production process.

### SUMMARY OF THE INVENTION

In view of the existing problems in the fixing device for the heat sink device or the shield case, a technical problem to be solved by the present application is to provide a fixing device for the heat sink device or the shield case, which can simplify assembly process, and avoid quality problems of a product due to unstable assembly.

In order to solve the above problems, the present invention provides a fixing device for connecting a heat sink device or a shield case to a circuit board, in the circuit board is provided with a via hole which has a first size, a second size, and a first height, wherein the fixing device comprises a base body which is connected with the heat sink device or the shield case; anda connecting member which is formed by bending and extending from the base body. The connecting member comprises successively along its extending direction a first boss part having a first width; a clamping part for engaging with the via hole, and having a second width and a second height; and a second boss part having a third width; wherein, the third width is smaller than the second size, so that the second boss part passes through the via hole along the second size; the second width substantially equals to the first size, the second height substantially equals to the first height, and both the first and third width are larger than the first size, so that after the second boss part passes through the via hole, the clamping part engages with the via hole, and after rotating the fixing device, the first and second boss part clamp the circuit board from both sides of the circuit board.

In the fixing device as described above, the fixing device is formed by a plate-shaped material.

In the fixing device as described above, the second boss part has a trapezoidal or triangular cross section.

In the fixing device as described above, the base body and the connecting member are perpendicular with each other.

The present invention further provides a heat sink device comprising a fixing device and a heat dissipating body which is connected with a circuit board by the fixing device, in the circuit board is provided with a via hole which has a first size, a second size, and a first height, wherein the fixing device comprises a base body which is connected with the heat sink device; and a connecting member which is formed by bending and extending from the base body. The connecting member comprises successively along its extending direction a first boss part having a first width; a clamping part for engaging with the via hole, and having a second width and a second height; and a second boss part having a third width; wherein the third width is smaller than the second size, so that the second boss part passes through the via hole along the second size; the second width substantially equals to the first size, the second height substantially equals to the first height, and both the first and third width are larger than the first size, so that after the second boss part passes through the via hole, the clamping part engages with the via hole, and after rotating the fixing device, the first and second boss part clamp the circuit board from both sides of the circuit board.

In the heat sink device as described above, the fixing device is formed by a plate-shaped material.

In the heat sink device as described above, the second boss part has a trapezoidal or triangular cross section.

In the heat sink device as described above, the base body and the connecting member are perpendicular with each other.

The present invention further provides a shield case comprising a fixing device and a case body which is connected with a circuit board by the fixing device, in the circuit board is provided with a via hole which has a first size, a second size, and a first height, wherein the fixing device comprises a base body which is connected with the case body in a fixed manner; and a connecting member which is formed by bending and extending from the base body. The connecting member comprises successively along its extending direction a first boss part having a first width; a clamping part for engaging with the via hole, and having a second width and a second height; and a second boss part having a third width; wherein the third width is smaller than the second size, so that the second boss part passes through the via hole along the second size; the second width substantially equals to the first size, the second height substantially equals to the first height, and both the first and third width are larger than the first size, so that after the second boss part passes through the via hole, the clamping part engages with the via hole, and after rotating the fixing device, the first and second boss part clamp the circuit board from both sides of the circuit board.

In the shield case as described above, the fixing device is formed by a plate-shaped material.

In the shield case as described above, the second boss part has a trapezoidal or triangular cross section.

In the shield case as described above, the base body and the connecting member are perpendicular with each other.

The beneficial effects of the present application lie in that, by virtue of the special structure of the fixing device, the heat sink device or the shield case, when connected to the circuit board, can be fixed by clamping and rotating. The present invention not only enables a convenient way for assembling, but also helps to reinforce the connection. In addition, the present invention can simplify assembly process, and avoid quality problems of a product due to unstable assembly.

The present invention will be described in details hereinafter by reference with the accompanying drawings and particular embodiments, which should not be construed as limitations to the present invention.

### BRIEF DESCRIPTION OF THE DRAWINGS

FIG. 1 is a structural schematic view showing a fixing device on a heat sink device in the prior art;

FIG. 2 is a front view showing a fixing device of the present invention;

FIG. 3 is a side view showing the fixing device in FIG. 2;

FIG. 4A is a schematic view showing a via hole in a circuit board according to an embodiment;

FIG. 4B is a schematic view showing a via hole in a circuit board according to another embodiment;

FIG. 5 is a schematic view showing the connection between a heat sink device and a circuit board according to the present invention (upon clamping); and

FIG. 6 is a schematic view showing the connection between a heat sink device and a circuit board according to the present invention (upon rotating).

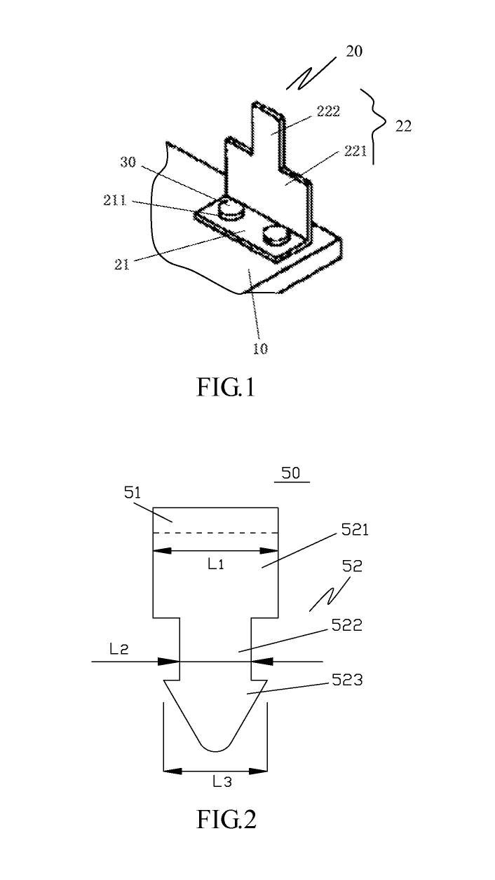

The referential numerals for elements are described as follows.
10 heat sink device
11 heat dissipating body, case body
20 fixing device
21 base member
211 via hole
22 connecting member
221 boss
222 connecting part
30 locking member
40 circuit board
41 via hole
50 fixing device
51 base body
511 via hole
52 connecting member
521 first boss part
522 clamping part
523 second boss part
L1 first width
L2 second width
L3 third width
K2 second thickness
K3 third thickness
h1 first height
h2 second height
L4 first size
L5 second size

### DETAILED DESCRIPTION OF THE PREFERRED EMBODIMENTS

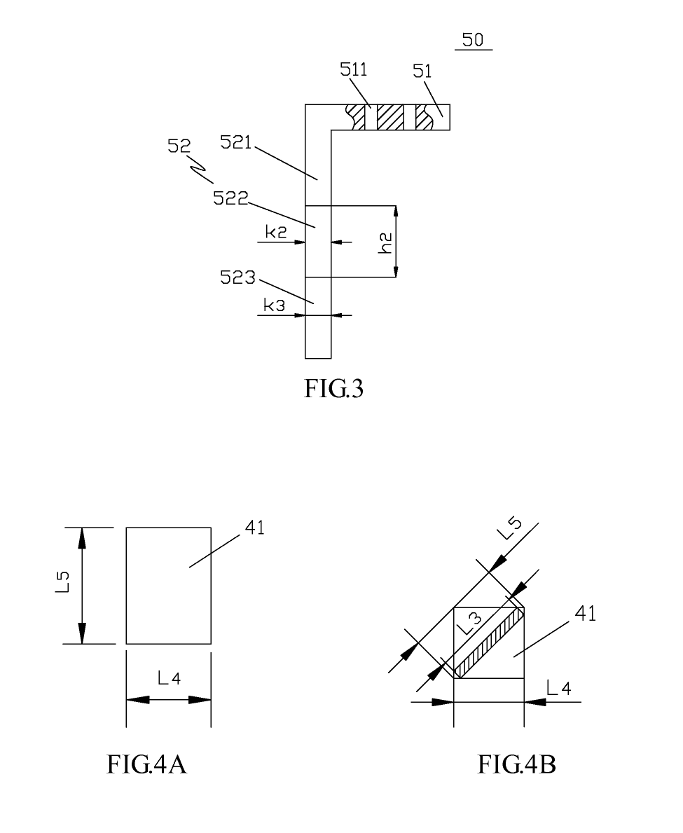

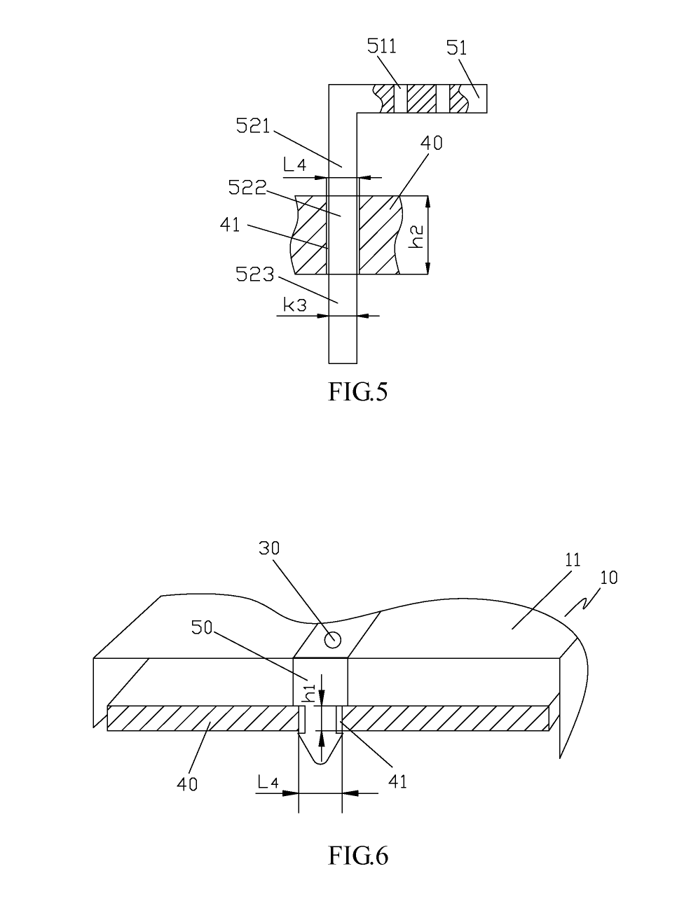

Hereinafter, technical solutions of the present application will be described in details in conjunction with the drawings and the preferred embodiments, so as to further understand objects, solutions, and effects of the present application but not to limit protection scopes of appended claims of the present application. According to the present invention, a fixing device is used to fix a heat sink device or a shield case onto a circuit board. As shown in FIGS. 2-3, the fixing device 50 comprises a base body 51 and a connecting member 52. On the base body 51 is arranged at least one via hole 511, through which a locking member 30 passes (see FIG. 6) to fixedly connect the fixing device 50 to the heat sink device or the shield case. The connecting member 52 is formed by bending and extending from the base body 51. The connecting member 52 comprises successively along its extending direction a first boss part 521, a clamping part 522, and a second boss part 523. The first boss part 521 is formed by bending from an end of the base body 51, and has a first width L1. The clamping part 522 is connected with an end of the first boss part 521 which is away from the base body 51. The clamping part 522 is used to engage with a via hole 41 in a circuit board 40. Referring to FIGS. 4A-4B, 5-6, the via hole 41 has a first size L4, a second size L5, and a first height h1, and the clamping part 522 has a second width L2, a second thickness K2, and a second height h2. The second boss part 523 is connected with an end of the clamping part 522 away from the first boss part 521, and has a third width L3 and a third thickness K3.

In order to realize a stable connection between the heat sink device or the shield case and the circuit board, it is required to take the following three issues into consideration: firstly, how the second boss part 523 can pass through the via hole 41; secondly, how the clamping part 522 is engaged with the via hole 41; and thirdly, how to fix the fixing device 50 and the circuit board 40.

Referring to FIGS. 4A and 5, the via hole 41 has a rectangular cross section, the first size L4 corresponds to the width of the rectangle, and the second size L5 corresponds to the length of the rectangle. In order to enable the second boss part 523 to successfully pass through the via hole 41, it is required that both the second and third thickness K2 and K3 should be smaller than the first size L4, and that the third width L3 should be smaller than the second size L5. In this way, by inserting the second boss part 523 in the direction of the second size L5 (i.e., the length direction of the via hole 41), it is possible for the second boss part 523 to successfully pass through the via hole 41. In order to realize the engaging of the clamping part 522 and the via hole 41, the second width L2 substantially equals to the first size L4 (it should be noted that the term “substantially equal” as used herein means that the second width L2 equals to the first size L4 within a suitable tolerance margin, and does not equal to the first size L4 absolutely), and the first height h1 substantially equals to the second height h2 (it should be noted that the term “substantially equal” as used herein means that the height h1 equals to the second height h2 within a suitable tolerance margin, and does not equal to the second height h2 absolutely). In order to fix the fixing device 50 with respect to the circuit board 40, the first and third width L1 and L3 are larger than the first size L4. In this way, once the second boss part 523 of the fixing device 50 passes through the via hole 41, and when the clamping part 522 is completely accommodated in the via hole 41 and the first and second boss part 521, 522 are located on both sides of the circuit board 40, respectively, the fixing device 50 is rotated to realize, by clamping the circuit board 40 with the first and second boss part 521, 522, a fixed connection between the fixing device 50 and the circuit board 40, so that the heat sink device or the shield case is fixed to the circuit board.

Referring to FIG. 4B, the via hole 41 has a square cross section, the first size L4 corresponds to the side of the square, and the second size L5 corresponds to the length of diagonal of the square. In order to enable the second boss part 523 to successfully pass through the via hole 41, it is required that the third width L3 should be smaller than the second size L5, and that the second boss part 523 should be able to pass through the via hole 41 in the direction of the second size L5 (i.e., the diagonal direction of the via hole 41). In order to realize the engaging of the clamping part 522 and the via hole 41, the second width L2 substantially equals to the first size L4 (it should be noted that the term “substantially equal” as used herein means that the second width L2 equals to the first size L4 within a suitable tolerance margin, and does not equal to the first size L4 absolutely), and the first height h1 substantially equals to the second height h2 (it should be noted that the term “substantially equal” as used herein means that the height h1 equals to the second height h2 within a suitable tolerance margin, and does not equal to the second height h2 absolutely). In order to fix the fixing device 50 with respect to the circuit board 40, the first and third width L1 and L3 are larger than the first size L4. In this way, once the second boss part 523 of the fixing device 50 passes through the via hole 41, and when the clamping part 522 is completely accommodated in the via hole 41 and the first and second boss part 521, 522 are located on both sides of the circuit board 40, respectively, the fixing device 50 is rotated to realize, by clamping the circuit board 40 with the first and second boss part 521, 522, a fixed connection between the fixing device 50 and the circuit board 40, so that the heat sink device or the shield case is fixed to the circuit board.

In the description mentioned above, only two examples of the via hole 41 are presented. However, in the practical application, the present invention is not limited to such examples. For example, the via hole 41 may also has an elliptical cross section. In other words, it is only required that the via hole 41 should have different sizes.

To facilitate the integral molding of the fixing device, the fixing device 50 can be formed by a plate-shaped material. As a result, the first boss part 521 has a same thickness as the second and third thickness K2 and K3, and the first boss part 521, the clamping part 522, and the second boss part 523 lie in the same plane.

To facilitate the second boss part 523 pass through the via hole 41, the second boss part 523 preferably has a trapezoidal or triangular cross section.

Furthermore, to facilitate the space utilization after the heat sink device or the shield case is fixed to the circuit board, the connecting member 52 and the base body 51 are perpendicular with each other.

Furthermore, the present invention provides a heat sink device which comprises the above-described fixing device 50. As shown in FIG. 6, the heat sink device 10 comprises a heat dissipating body 11 and the fixing device 50. The locking member 30 passes through a via hole (not shown) in the heat dissipating body 11 and the via hole 511 in the base body, so that the heat dissipating body 11 and the fixing device 50 are connected in a fixed manner. The structure regarding the heat dissipating body 11 belongs to the prior art, and thus is not discussed here for simplicity.

The present invention further provides a shield case which comprises the above-described fixing device 50. The shield case mainly consists of a case body (equivalent to the heat dissipating body 11 in FIG. 6) and the fixing device 50. The locking member 30 passes through a via hole (not shown) in the case body 11 and the via hole 511 in the base body, so that the case body 11 and the fixing device 50 are connected in a fixed manner. The structure regarding the case body 11 belongs to the prior art, and thus is not discussed here for simplicity.

The present invention certainly has many other embodiments. Various modifications and variations to the present invention may occur to the skilled in the art without departing from the spirit and nature of the present invention, and such modifications and variations should fall within the scope of the appending claims of the present invention.

What is claimed is:

1. A fixing device for connecting a heat sink device or a shield case to a circuit board, in said circuit board is provided with a via hole which has a first size, a second size, and a first height, wherein the fixing device comprises:
a base body which is connected with the heat sink device or the shield case; and
a connecting member which is formed by bending and extending from the base body,
the connecting member comprises successively along its extending direction:
a first boss part having a first width;
a clamping part for engaging with the via hole, and having a second width and a second height; and
a second boss part having a third width,
wherein, the third width is smaller than the second size, so that the second boss part passes through the via hole along the second size; the second width substantially equals to the first size, the second height substantially equals to the first height, and both the first and third width are larger than the first size, so that after the second boss part passes through the via hole, the clamping part engages with the via hole, and after rotating the fixing device, the first and second boss part clamp the circuit board from both sides of the circuit board.

2. The fixing device according to claim 1, wherein the fixing device is formed by a plate-shaped material.

3. The fixing device according to claim 1, wherein the second boss part has a trapezoidal or triangular cross section.

4. The fixing device according to claim 1, wherein the base body and the connecting member are perpendicular with each other.

5. A heat sink device, comprising a fixing device and a heat dissipating body which is connected with a circuit board by the fixing device, in the circuit board is provided with a via hole which has a first size, a second size, and a first height, wherein the fixing device comprises:
a base body which is connected with the heat sink device; and
a connecting member which is formed by bending and extending from the base body,
the connecting member comprises successively along its extending direction:
a first boss part having a first width;
a clamping part for engaging with the via hole, and having a second width and a second height; and
a second boss part having a third width;
wherein the third width is smaller than the second size, so that the second boss part passes through the via hole along the second size; the second width substantially equals to the first size, the second height substantially equals to the first height, and both the first and third width are larger than the first size, so that after the second boss part passes through the via hole, the clamping part engages with the via hole, and after rotating the fixing device, the first and second boss part clamp the circuit board from both sides of the circuit board.

6. The heat sink device according to claim 5, wherein the fixing device is formed by a plate-shaped material.

7. The heat sink device according to claim 5, wherein the second boss part has a trapezoidal or triangular cross section.

8. The heat sink device according to claim 5, wherein the base body and the connecting member are perpendicular with each other.

9. A shield case, comprising a fixing device and a case body which is connected with a circuit board by the fixing device, in the circuit board is provided with a via hole which has a first size, a second size, and a first height, wherein the fixing device comprises:
a base body which is connected with the case body in a fixed manner; and
a connecting member which is formed by bending and extending from the base body;
the connecting member comprises successively along its extending direction:
a first boss part having a first width;
a clamping part for engaging with the via hole, and having a second width and a second height; and
a second boss part having a third width;
wherein the third width is smaller than the second size, so that the second boss part passes through the via hole along the second size; the second width substantially equals to the first size, the second height substantially equals to the first height, and both the first and third width are larger than the first size, so that after the second boss part passes through the via hole, the clamping part engages with the via hole, and after rotating the fixing device, the first and second boss part clamp the circuit board from both sides of the circuit board.

10. The shield case according to claim 9, wherein the fixing device is formed by a plate-shaped material.

11. The shield case according to claim 9, wherein the second boss part has a trapezoidal or triangular cross section.

12. The shield case according to claim 9, wherein the base body and the connecting member are perpendicular with each other.
